(19) United States
(12) Patent Application Publication
(10) Pub. No.: US 2005/0184756 A1
(43) Pub. Date: Aug. 25, 2005

(54) Method and circuit arrangement for the generation of ternary signals

(76) Inventors: Johannes Hohl, Villach (AT); Pessl Peter, Villach (AT)

Correspondence Address: BRINKS HOFER GILSON & LIONE, P.O. BOX 10395, CHICAGO, IL, 60610, US

(21) Appl. No.: 10/985,591

(22) Filed: Nov. 10, 2004

(30) Foreign Application Priority Data
Nov. 12, 2003 (DE) 103 52 812.1

(51) Int. Cl. H03K 19/00

(52) U.S. Cl. 326/59

(57) ABSTRACT

This application provides a circuit arrangement for a circuit output structure that generates ternary signals. The output structure includes a switching means for connecting a signal output with a first potential for producing a first signal level. A further switching means connects the signal output with a second potential for producing a second signal level. The signal output also is connected through a resistance means to a third potential that provides a third signal level. The switching means and the further switching means may decouple the signal output from the first potential and the second potential when a control voltage for controlling the switching means and the further switching means is removed or floats. When the first potential and the second potential are decoupled, the signal output may attain the level of the third potential.

### RELATED APPLICATIONS

The present patent document claims priority under 35 U.S.C. § 119(a)-(d) to German Application 103 52 812. 1, filed in Germany on Nov. 12, 2003, which is hereby incorporated by reference.

### BACKGROUND

1. Technical Field

The present invention relates to a method and a circuit arrangement for the generation of ternary signals, in particular, the output of ternary signals from an output structure of a semiconductor module.

2. Background Information

Ternary interfaces may produce signal outputs that have three active states and are used with semiconductor modules having a small number of connections. The ternary interfaces may be analog semiconductor modules and can include line drivers for fan-out purposes.

The three active states of an output structure of a ternary interface are graphically represented in FIG. 1. The different signal levels HI, MID, and LO may be potential levels or voltages which are derived from a supply voltage of a circuit. While increasingly smaller supply voltages are used with semiconductor modules, in order to provide lower loss values and achieve higher speeds, a comparatively high voltage of 3.3 V may be used to establish the reference potentials for the signal outputs.

In order to form a ternary signal output, the circuit of FIG. 2 may be utilized. FIG. 2 is a schematic of a prior art output structure 20′ of a semiconductor module that provides a ternary signal. The output structure 20′ includes a driver 10′ and a voltage generator 30′. In such a circuit, the supply voltage V_{S} may represent a HI signal level. The HI level may have a potential of 3.3V. The second voltage MID is a lower potential than the supply voltage V_{S}. For the generation of the second voltage, the voltage generator 30′ may be required. However, providing the voltage generator 30′ of FIG. 2 may require a greater expenditure and effort. The ground potential V_{G} will supply the LO signal. The combination of these three signals form the basis for the ternary signal levels available at the signal output 1′ of the semiconductor module, which are made available to a driver 10′.

Alternatively, a higher voltage that will be used as a signal output may be introduced to the semiconductor module from an outside source. By way of example, where a semiconductor module has an internal supply voltage of 1.5 V, it may be possible for a voltage of 3.3 V to be introduced from outside. In many circuit environments, a higher external supply voltage is available in addition to the lower internal supply voltage of the semiconductor modules. To conduct the external supply voltage into the semiconductor module, however, an additional connection is required. In addition, problems may arise with respect to over-voltage protection for the internal structures of the semiconductor module.

### BRIEF SUMMARY

This application provides a circuit arrangement for an output structure and a method that will generate a ternary signal output for a semiconductor module. The circuit arrangement includes a switching means for connecting the signal output of the circuit output structure with a first potential that produces a first signal level. Also included in the circuit arrangement is a further or second switching means for connecting the signal output with a second potential that produces a second signal level. The signal output may be connected to an external source that provides a third potential. Between the third potential and the signal output is a resistance means that provides a resistance value. The resistance means may be a resistor. The switching means and the further switching means may decouple the first potential and the second potential from the signal output so that the signal output reaches the voltage level of the third potential. The first potential may be a ground potential. The second potential may be a power supply potential of the output structure. The third potential may be a potential that is greater than the power supply potential of the output structure.

The switching means and the further switching means may be controlled with control signals. The switching means and the further switching means may be a first transistor and a second transistor. The transistor may be a bipolar junction transistor or a metal-oxide semiconductor field effect transistor (“MOSFET”). When the transistor used is a MOSFET transistor, the first and second transistors may be arranged in a complementary mode (“CMOS”). The control signals may be binary signals that are fed directly to a gate or base on the first and second transistor. Preferably, the binary signals are fed to a conditioner or a control block that will provide a single control signal that will control the first and second transistor.

When no control voltage is applied to the first transistor and the second transistor, the transistors may have a resistance that is greater than the resistance of the resistance means. When the transistors have a resistance that is greater than the resistance means, the signal output is essentially decoupled from the first potential and the second potential. In this state, a signal level is imposed at the signal output which corresponds substantially to the third potential.

Further advantages of the invention can be derived from the following detailed description. Other systems, methods, features and advantages of the invention will be, or will become, apparent to one with skill in the art upon examination of the following figures and detailed description. It is intended that all such additional systems, methods, features and advantages be included within this description, be within the scope of the invention, and be protected by the following claims

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a graph showing a ternary signal with three signal levels.

FIG. 2 is a prior art output structure for ternary signals.

FIG. 3 is a circuit diagram of a circuit arrangement of an output structure of a semiconductor module.

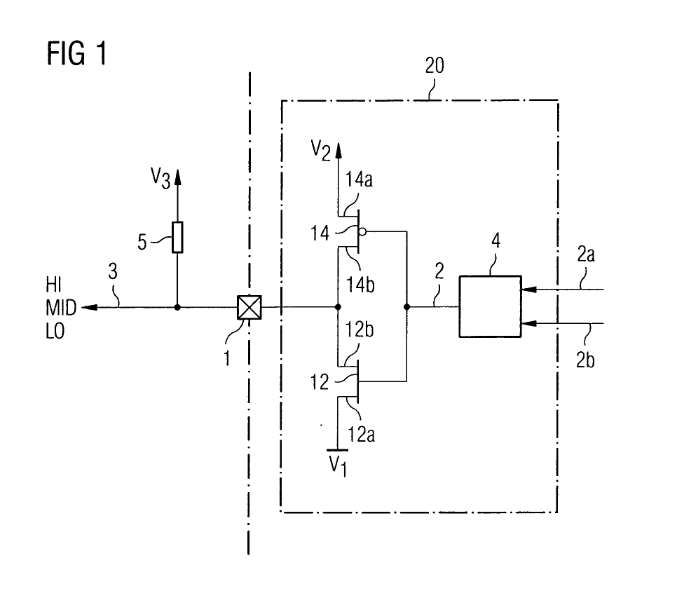

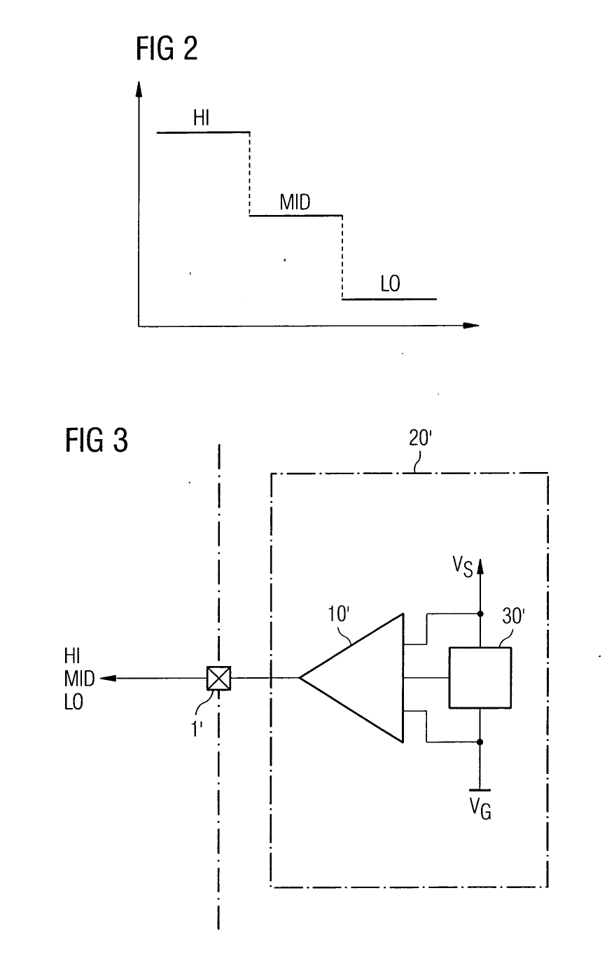

### DETAILED DESCRIPTION OF THE DRAWINGS AND THE PRESENTLY PREFERRED EMBODIMENTS

FIG. 3 is a diagram of a circuit arrangement for realizing an output structure 20 for producing a ternary signal 3 according to one embodiment of the invention. The output structure 20 may comprise a switching means and a further switching means in the form of a first transistor 12 and a second transistor 14. The transistors 12, 14 in this embodiment may be metal-oxide semiconductor field-effect transistors (“MOSFET”) connected in series between the power supply V₂ and ground potential V₁. The charge carrier types of the transistors 12, 14, are selected such that one transistor may be a PMOS transistor and the other an NMOS transistor. The combination of the NMOS and PMOS transistors 12, 14 form an inverter structure or a complementary (“CMOS”) combination.

Each transistor 12, 14 has a control voltage connection. For a CMOS structure, the control connection 2 is a gate on each of the transistors 12, 14. In the embodiment of FIG. 3, the control connection 2 is common to both transistors 12, 14.

The first transistor 12 has a connection 12a connected with a first potential V₁. The potential V₁ may be a ground potential. A further connection 12b of the first transistor 12 is connected to a signal output 1 of the output structure 20 and to a connection 14b of the second transistor 14. A further connection 14a of the second transistor 14 is connected to a second potential V₂. The second potential V₂ may be an internal supply voltage for the output structure 20, which in this embodiment is 1.5 V.

The signal output 1 of the output structure 20 is connected via a resistance means 5 in the form of a conventional resistor to a third potential V₃. The resistance means 5 may have a resistance on the order of 1 kΩ to 100 kΩ. The third potential V₃ is an external voltage supply in a circuit environment of the semiconductor module, which may be approximately 3.3 V. The ternary signal 3 may be tapped at the signal output 1 of the output structure 20.

The function of the output structure 20 may be explained in connection with a method for producing the ternary signal 3 in a preferred embodiment. According to one method, a first signal level may be produced at a signal output 1 by connecting the signal output 1 to a first potential. A second signal level is produced by connecting the signal output 1 to a second potential. To produce a third signal level, the signal output 1 is connected via a resistance means 5 to a third potential and the signal output 1 is decoupled from the first potential and the second potential. The third signal level is produced at the signal output 1.

The first potential can be a ground potential V₁, the second potential an internal supply voltage V₂ of a semiconductor module, and the third potential an external supply voltage V₃, which differs from the internal supply voltage of the output structure 20. The internal supply voltage V₂ may be 1.5 Volts while the external supply voltage V₃ may be 3.3 Volts. Utilizing the present method and the embodiment described above, the ternary signal output 1 may be produced without an additional voltage generated internally in the corresponding output structure 20 or by supplying an external voltage to the output structure 2. It is therefore possible for the number of connections for the semiconductor module to remain at a minimum.

In the preferred embodiment, the transistors 12, 14 may be controlled and actuated with a common control signal 2. The control signal 2 is generated in a control block 4 and is dependent upon binary signals 2a, 2b which may assume one of two states. The control block 4 may be designed in such a way that the control signal 2 may assume one of two possible values or that the input to the transistors be allowed to float or remain potential-free.

In an example for producing a LO signal, a control signal 2 may be applied to a gate of the transistors 12, 14 so that the first transistor 12 adopts a low-resistance state, while the second transistor 14 adopts a high-resistance state. In this case, the signal output 1 of the output structure 20 is connected along a path with low resistance to the first potential V₁. The first potential V₁ may have a potential that equals ground or earth potential and is provided at the signal output 1 as first signal level LO.

The voltage of the first signal level LO corresponds substantially to the level of the ground potential V₁. A volume resistance of the first transistor 12, that is the resistance between the connection 12a and the connection 12b, is substantially less than the resistance of the resistance means 5. The volume resistance of the second transistor 14, that is the resistance between the connection 14a and the connection 14b, is substantially higher than the resistance 5. The resistances of the transistors 12, 14 ensure that the voltage present at signal output 1 is approximately equal to the ground potential.

In an example for producing a MID signal output, the transistors 12, 14 may be controlled and actuated by applying the control signal to the control connection 2 so that the second transistor 14 adopts a low-resistance state and the first transistor 12 adopts a high-resistance state. The signal output 1 of the output structure 20 is connected through the low-resistance of the second transistor 14 to the second potential V₂. The second potential V₂ may be the supply voltage V₂ to the output structure 20. The second potential V₂ will establish the value of the second signal level MID imposed at the signal output 1. In a preferred embodiment, the supply voltage of the semiconductor module may be 1.5 V. In this state, the forward resistance of the second transistor 14 may be substantially lower than the resistance of the resistance means 5 and the forward resistance of the first transistor 12 is substantially higher than the resistance of the resistance means 5.

In an example for producing a HI signal output, the common control signal applied to the control connection 2 for the transistors 12, 14 may be switched off, removed or allowed to float and be potential-free. Both the first transistor 12 and the second transistor 14 will adopt a high-resistance state. The high-resistance of the transistors 12, 14 will decouple the signal output from the first potential and the second potential sources. Therefore, the signal output 1 connects to the third potential source V₃ via the resistance means 5. The third potential V₃ may be an external supply voltage that provides a third signal level HI at the signal output 1. The external supply voltage may be 3.3 V. To provide a HI voltage level that reflects the potential of the external supply, the resistance of the first transistor 12 and the resistance of the second transistor 14 should be substantially higher than the resistance of the resistance means 5. The signal output 1 and the ternary signal 3 are essentially the same point electrically, thus whatever signal is present at the signal output 1 also may be present at the ternary signal 3 in FIG. 3.

The conditions for obtaining the results for all three signal outputs may be optimized by selecting the value of the resistance means 5 to correspond with the resistances of transistors 12, 14. The resistances for the transistors 12, 14 may be obtained through dimensioning and configuring of the transistors 12, 14. The resistance value of the resistance means may range from 1 kΩ to 100 kΩ.

In the embodiment described, a common signal was applied to the control connection 2 of the transistors 12, 14 simultaneously. The transistors 12, 14 are controlled and actuated by the common control signal from the control block 4. As an alternative, however, it is possible for the transistors 12, 14 to be actuated and controlled separately. In other words, the binary signals 2a, 2b may be applied directly to the gates of transistors 12, 14 respectively. Therefore, a conversion of the binary signals 2a, 2b is effected directly to the transistors 12, 14, thus the control block 4 may be omitted. Further, the binary signals 2a, 2b may be allowed to float simultaneously in order to provide the decoupling of the potentials V₁, V₂ so that the third potential V₃ may be realized.

The signal output 1 is connected via a resistance means 5 to the third potential V₃. The resistance means 5 may be an external resistor outside of the output structure 20. There may be several output structures 20 in a semiconductor module. The resistance means 5 may be internal to the semiconductor module but yet still remain external to each of the output structures 20. Where the semiconductor module comprises several output structures 20, the resistance means 5 may be made available to the other output structures 20 that are connected to the ternary signal 3.

The method and the corresponding circuit arrangement for the output structure 20 of a semiconductor module offer an advantage that the ternary signal 3 may be produced from an output structure 20 that occupies a small surface area of a semiconductor chip. Another advantage that may be realized is the reduction in the number of connection pins. The output structure may be operated in a manner similar to a standard binary output structure having only two active states. The third potential may be provided externally when the control voltages are allowed to float effectively decoupling the potentials V₁, V₂ from the signal output. In addition, there is no need to provide a second supply voltage to the output structure 20. With the higher potential of the second power supply V₃ in another module, problems regarding over-voltage protection for internal structures, particularly the output structure 20 of the semiconductor module may be avoided.

It is therefore intended that the foregoing detailed description be regarded as illustrative rather than limiting, and that it be understood that it is the following claims, including all equivalents, that are intended to define the spirit and scope of this invention.

1. A circuit arrangement for a circuit output structure for generating ternary signals, comprising:
a switching means for connecting a signal output for the circuit output structure with a first potential for the production of a first signal level; and
a further switching means for connecting the signal output with a second potential for the production of a second signal level, wherein the signal output is connected via a resistance means to a third potential, and that the switching means and the further switching means decouple the first potential and the second potential simultaneously producing a third signal level.

2. The circuit arrangement of claim 1, wherein the first signal level is produced when the switching means is controlled having a forward resistance that is lower than a resistance of the resistance means and the further switching means is controlled having a forward resistance that is greater than the resistance of the resistance means, the second signal level is produced when the switching means is controlled having the forward resistance that is greater than the resistance of the resistance means and the further switching means is controlled having the forward resistance that is lower than the resistance of the resistance means, and the third signal level is produced when the switching means and the further switching means are controlled having forward resistances that are greater than the resistance of the resistance means.

3. The circuit arrangement of claim 1, further comprising a control block for producing a control voltage that is a function of binary signals and controls the switching means and the further switching means.

4. The circuit arrangement of claim 3, wherein the switching means and the further switching means are controlled by an absence of a control voltage.

5. The circuit arrangement of claim 4, wherein the third signal level is produced when no control voltage is applied to the switching means and the further switching means.

6. The circuit arrangement of claim 3, wherein the switching means and the further switching means are controlled by the same control voltage.

7. The circuit arrangement of claim 3, wherein the switching means and the further switching means are controlled separately by a control voltage.

8. The circuit arrangement of claim 1, wherein the switching means and the further switching means are connected in series between the first potential and the second potential and a connection point between the switching means and the further switching means is connected to the signal output.

9. The circuit arrangement of claim 1, wherein the switching means and the further switching means are transistors.

10. The circuit arrangement of claim 1, wherein the resistance means is integrated into a semiconductor module that includes the output structure.

11. The circuit arrangement of claim 1, wherein the resistance means is provided externally outside the output structure.

12. A method for generating ternary signals comprising the steps of:
connecting a signal output to a first potential to produce a first signal level;
connecting the signal output to a second potential to produce a second signal level; and
decoupling the signal output from the first potential and the second potential to produce a third signal level wherein the signal output is connected to a third potential via a resistance means from outside an output structure that provides the connecting of the first potential and the second potential.

13. The method of claim 14, wherein the first potential is derived from a ground potential and the second potential is derived from a supply voltage of the output structure.

14. The method of claim 14, wherein the third potential is derived from an external supply voltage.

15. The method of claim 14, wherein the connecting is performed by a first transistor and a second transistor.

16. The method of claim 15, wherein the connecting and the decoupling are performed as a function of a control signal applied to the first transistor and a control signal applied to the second transistor.

17. The method of claim 14, wherein the control signal applied to the first transistor and the control signal applied to the second transistor is the same control signal.

18. A circuit arrangement for a circuit output structure for generating ternary signals, comprising:
a first transistor for connecting a signal output of the circuit output structure with a first potential for producing a first signal level where the transistor is controlled with a control signal to provide a low resistance path between the first potential and the signal output; and
a second transistor for connecting the signal output with a second potential for producing a second signal level where the second transistor is controlled with the control signal to provide a low resistance path between the second potential and the signal output,
wherein the signal output is connected via a resistor to a third potential, and the first transistor and the second transistor, when the control signal is not applied to the first transistor and the second transistor, each have a resistance greater than the resistor thereby decoupling the first potential and the second potential from the signal output producing a third signal level approximating the third potential at the signal output.

19. The circuit arrangement of claim 18, further comprising a control block for developing the control voltage for controlling and actuating the first transistor and the second transistor.

20. The circuit arrangement of claim 18, wherein the resistor and the third potential are provided externally to the output structure.
